(19) United States
(12) Patent Application Publication
(10) Pub. No.: US 2025/0147129 A1
(43) Pub. Date: May 8, 2025

(54) MAGNETORESISTIVE SENSOR

(71) Applicant: Infineon Technologies AG, Neubiberg (DE)

(72) Inventors: Bernhard ENDRES, Nabburg (DE); Andreas STRAßER, Regensburg (DE)

(21) Appl. No.: 18/939,078

(22) Filed: Nov. 6, 2024

(30) Foreign Application Priority Data
Nov. 7, 2023 (DE) 102023130715.0

(51) Int. Cl. G01R 33/09; G01L 1/12; H10N 50/10; H10N 50/85

(52) U.S. Cl. CPC G01R 33/098; G01L 1/125; G01R 33/093; G01R 33/096; H10N 50/10; H10N 50/85

(57) ABSTRACT

The present disclosure relates to a magnetoresistive sensor. The magnetoresistive sensor includes at least one sensor element having a layer stack. The layer stack includes a magnetically free layer with a magnetically free magnetization. A measurement sensitivity of the sensor element is temperature-dependent. The magnetoresistive sensor also includes a device which is configured to induce a temperature-dependent mechanical stress in the magnetically free layer. The temperature dependence of the measurement sensitivity can be at least partially compensated for by the temperature-dependent mechanical stress.

### CROSS-REFERENCE TO RELATED APPLICATION

This application claims priority to Germany Patent Application No. 102023130715.0 filed on Nov. 7, 2023, the content of which is incorporated by reference herein in its entirety.

### TECHNICAL FIELD

The present disclosure relates generally to magnetoresistive sensors and in particular to magnetoresistive sensors with compensation for a temperature dependence of their measurement sensitivity.

### BACKGROUND

Magnetic field sensors based on a magnetoresistance effect are referred to as magnetoresistive sensors and are used in applications for measuring magnetic fields, for example for measuring current, measuring positions and measuring angles. Magnetoresistance is the property of a material to change its electrical resistance when an external magnetic field is applied to the material. On account of a high signal level and high accuracy of magnetoresistive sensors and the possibility of integrating magnetoresistive sensors in complementary metal oxide semiconductor (CMOS) and bipolar CMOS (BiCMOS) technologies, magnetoresistive sensors may be a better choice than Hall-based sensors. Some types of magnetoresistive sensors include anisotropic magnetoresistance sensors (AMR), giant magnetoresistance sensors (GMR) and tunnel magnetoresistance sensors (TMR), each of which uses a corresponding magnetoresistive effect.

Various magnetoresistive effects can be abbreviated with xMR, where the “x” is used as a placeholder for the various magnetoresistive effects. xMR sensors may capture an orientation of an applied magnetic field by measuring sine and cosine angle components using monolithically integrated magnetoresistive sensor elements. In this case, the acronym of the xMR sensor respectively denotes the magnetoresistive effect that is used to measure a corresponding magnetic field. The GMR effect is a quantum-mechanical magnetoresistance effect that is observed in thin-film structures which consist of alternately ferromagnetic and non-magnetic conductive layers. The TMR effect occurs at a magnetic tunnel junction (MTJ), wherein the magnetic tunnel junction occurs at a thin insulator that separates two ferromagnets from one another. The AMR effect is a material property in which a dependence of the electrical resistance on an angle between the direction of an electrical current (for example a scanning axis) and the magnetization direction is observed. The magnetoresistive effect can be associated with the sensitivity of an xMR sensor. For example, the magnetoresistive effect can be increased in order to increase the sensitivity of the xMR sensor.

A measurement sensitivity of an xMR sensor element may change with the temperature. In the case of tunnel magnetoresistive (TMR) resistors, the temperature coefficient of the TMR effect has a negative sign. That is to say, the TMR effect and therefore measurement sensitivity may decrease with increasing temperature.

There is therefore a need for concepts for the temperature compensation for the measurement sensitivity in magnetoresistive sensors.

### SUMMARY

A first aspect of the present disclosure relates to a magnetoresistive sensor having at least one sensor element (xMR resistance element). The sensor element is formed by a layer stack which (in addition to a reference layer or a reference system with a fixed magnetization) includes a magnetically free layer with a magnetically free magnetization. A measurement sensitivity of the sensor element (and therefore possibly also of the magnetoresistive sensor) is temperature-dependent. For example, the measurement sensitivity of the sensor element may decrease with increasing temperature. The measurement sensitivity is a measure of how strongly the electrical resistance of the sensor element reacts to changes in the applied external magnetic field. A higher measurement sensitivity value means that the sensor element reacts more sensitively to magnetic field changes and can capture smaller magnetic field changes. In order to compensate for the temperature-dependent measurement sensitivity, the magnetoresistive sensor includes a device which is configured to induce a temperature-dependent mechanical stress in the magnetically free layer. The device therefore causes a temperature-dependent deformation of the magnetically free layer. The device is also referred to as a stress-inducing device below. The mechanical stress induced in a temperature-dependent manner in the magnetically free layer makes it possible to change a magnetic property of the magnetically free layer in a temperature-dependent manner, which is also known as (inverse) magnetostriction. As a result of the mechanical stress induced in a temperature-dependent manner, the measurement sensitivity of the (xMR) sensor element may remain substantially the same at least in a particular direction if the temperature varies.

According to some implementations, the stress-inducing device is configured to exert a temperature-dependent mechanical force on the magnetically free layer in order to induce the mechanical stress in the magnetically free layer along a mechanical stress axis. In this case, the stress axis may be, for example, in a plane which is spanned by the magnetically free layer. The temperature-dependent mechanical stress in the magnetically free layer along the mechanical stress axis changes the magnetic properties of the magnetically free layer and therefore of the xMR sensor element. The temperature-dependent mechanical stress along the mechanical stress axis in the magnetically free layer ideally compensates for the temperature dependence of the xMR sensor element, with the result that its measurement sensitivity becomes substantially (more) temperature-independent.

According to some implementations, a direction of the mechanical force exerted by the stress-inducing device on the magnetically free layer is dependent on a temperature change. For example, a compressive force can be exerted as the temperature increases, whereas a tensile force can be exerted as the temperature drops, or vice versa.

According to some implementations, the stress-inducing device is configured to exert the temperature-dependent mechanical force on the magnetically free layer in a manner perpendicular or parallel to the mechanical stress axis in order to deform the magnetically free layer. In other words, the stress-inducing device may be configured to exert the temperature-dependent mechanical force on the magnetically free layer in a manner perpendicular or parallel to a plane that is spanned by the magnetically free layer.

In principle, different configurations of the stress-inducing device are possible. For example, the stress-inducing device could include a controlled system consisting of a temperature sensor and an actuator (for example a piezoelectric element) coupled thereto. The actuator could therefore be controlled in a temperature-dependent manner in order to induce the temperature-dependent mechanical stress along the mechanical stress axis in the magnetically free layer. In another configuration, the stress-inducing device may have one or more stress-inducing layers having a coefficient of thermal expansion that may be greater than that of the xMR layer stack or of the magnetically free layer, for example. According to some implementations, the stress-inducing device therefore has a stress-inducing layer which is mechanically coupled to the xMR layer stack and is configured to exert a temperature-dependent force on the magnetically free layer in order to induce the mechanical stress along the mechanical stress axis in the magnetically free layer.

According to some implementations, the stress-inducing layer has shape anisotropy. This means that a length and a width (and possibly a height) of the stress-inducing layer are not the same, but rather the length is considerably greater than the width, for example. Therefore, the stress-inducing layer also expands to different degrees in different directions due to the temperature.

According to some implementations, a material of the stress-inducing layer has a coefficient of thermal expansion of greater than 10 ppm/K, greater than 15 ppm/K, or greater than 20 ppm/K. Examples of such materials of the stress-inducing layer are aluminum, copper or nickel.

According to some implementations, the layer stack of the xMR sensor element is arranged between a first and a second electrode of the sensor element. The stress-inducing layer may be formed by one of the electrodes, for example. The stress-inducing layer may therefore combine a plurality of functions.

According to some implementations, the magnetoresistive sensor also includes a further stress-inducing device (for example a further stress-inducing layer) which is mechanically coupled to the second electrode and is configured to exert a further temperature-dependent mechanical force on the second electrode in order to induce or intensify the mechanical stress in the magnetically free layer. The further stress-inducing device (for example the further stress-inducing layer) may be arranged with a lateral offset with respect to the (first) stress-inducing device, with the result that their mechanical forces complement one another.

According to some implementations, an electrically conductive material for transmitting forces is arranged between the stress-inducing layer and the layer stack and is harder and/or stronger than the stress-inducing layer. For example, this may be a ceramic, for example titanium nitride (TiN). Hardness denotes the mechanical resistance with which a material opposes the mechanical penetration of another body. Hardness differs from strength which is the ability of a material to resist deformation and separation.

According to some implementations, the magnetically free layer has an iron alloy (for example CoFe, CoFeB, NiFe, etc.). The magnetostriction constant of the magnetically free layer can be adjusted using the iron content.

According to some implementations, the sensor element is in the form of a TMR sensor element.

According to some implementations, the magnetically free layer has a vortex magnetization. In an xMR sensor element, the free layer is one of the ferromagnetic layers and its magnetization can assume different configurations. One of these configurations is the vortex state. In the vortex state, the magnetization circulates around a central core within the free layer.

A further aspect of the present disclosure relates to a method for influencing a temperature-dependent measurement sensitivity of a magnetoresistive sensor. The method includes arranging at least one (xMR) sensor element having a layer stack on a substrate, wherein the layer stack includes a magnetically free layer with a magnetically free magnetization, and exerting a temperature-dependent mechanical force on the magnetically free layer in order to induce a mechanical stress in the magnetically free layer.

Yet another aspect of the present disclosure relates to a magnetoresistive sensor having at least one TMR sensor element having a magnetically free layer, wherein a measurement sensitivity of the TMR sensor element is temperature-dependent, and a stress-inducing layer which is mechanically coupled to the TMR sensor element, has a coefficient of thermal expansion and is configured to induce a temperature-dependent mechanical stress in the magnetically free layer.

According to some implementations, the stress-inducing layer has shape anisotropy.

According to some implementations, a material of the stress-inducing layer has a coefficient of thermal expansion of greater than 10 ppm/K. Examples of such materials of the stress-inducing layer are aluminum, copper or nickel.

According to some implementations, the TMR sensor element is arranged between a first and a second electrode, and the stress-inducing layer is formed by the first electrode and/or the second electrode.

### BRIEF DESCRIPTION OF THE DRAWINGS

Some examples of apparatuses and/or methods are explained in more detail below merely by way of example with reference to the accompanying figures, in which:

FIG. 1 shows an example of a layer stack of a magnetoresistive sensor element;

FIG. 2 shows an illustration of an inverse magnetostrictive effect;

FIG. 3A shows a magnetoresistive sensor having a stress-inducing device;

FIG. 3B shows a magnetoresistive sensor having a stress-inducing layer;

FIG. 3C shows a plan view of the magnetoresistive sensor from FIG. 3B;

FIG. 4 shows an extent based on a width and thickness of a stress-inducing layer;

FIG. 5 shows a plan view of a magnetoresistive sensor according to one or more implementations;

FIG. 6A shows a magnetoresistive sensor according to one or more implementations;

FIG. 6B shows an electrically conductive material for transmitting forces between the stress-inducing layer and the layer stack;

FIG. 7 shows a magnetoresistive sensor according to one or more implementations;

FIG. 8A shows a temperature dependence of the measurement sensitivity; and

FIG. 8B shows a measurement sensitivity with different stress-induced uniaxial anisotropy of a vortex-magnetized free layer.

### DETAILED DESCRIPTION

Some examples are now described in more detail with reference to the accompanying figures. However, further possible examples are not restricted to the features of these implementations that are described in detail. These may include modifications of the features, as well as equivalents and alternatives to the features. Furthermore, the terminology used herein to describe specific examples should not be restrictive for further possible examples.

The same or similar reference signs relate throughout the description of the figures to the same or similar elements or features, which may each be implemented identically or else in a modified form, while providing the same or a similar function. In the figures, the thicknesses of lines, layers and/or regions may also be exaggerated for clarification

When two elements A and B are combined using an “or”, this should be understood as meaning that all possible combinations are disclosed, e.g., only A, only B, and also A and B, unless expressly defined otherwise in the individual case. “At least one of A and B” or “A and/or B” may be used as alternative wording for the same combinations. This applies equivalently to combinations of more than two elements.

If a singular form, e.g., “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it goes without saying that the terms “comprises”, “comprising”, “has” and/or “having” when used describe the presence of the stated features, whole numbers, steps, operations, processes, elements, components and/or a group thereof, but do not thereby exclude the presence or the addition of one or more other features, whole numbers, steps, operations, processes, elements, components and/or a group thereof.

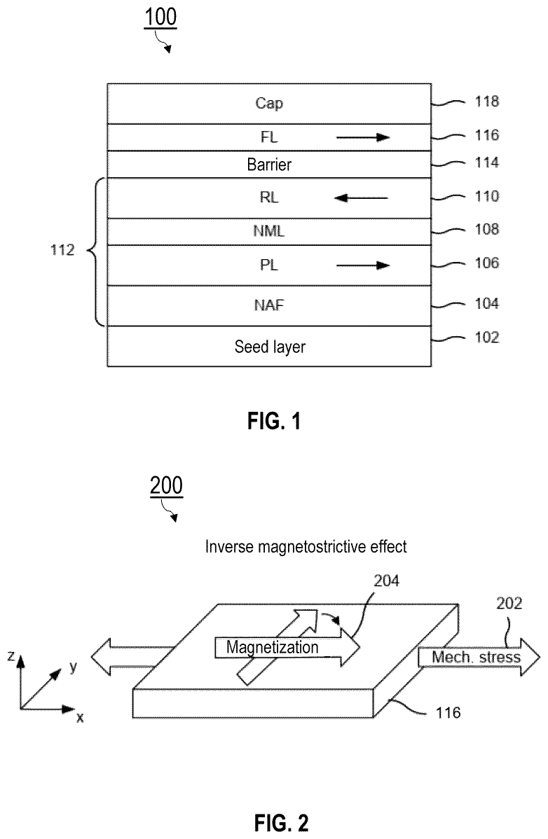

FIG. 1 shows an example of a layer stack of a magnetoresistive sensor element 100 according to one or more implementations.

The magnetoresistive sensor element 100 may be, for example, a TMR sensor element with a bottom-pinned spin-valve (BSV) configuration. GMR sensor elements are likewise possible. In addition, the magnetoresistive sensor element 100 may be arranged on a semiconductor substrate (not illustrated) of a magnetoresistive sensor. When described in a Cartesian coordinate system with coordinate axes x, y and z which are perpendicular to one another in pairs, the layers of the layer stack extend laterally in an xy plane which is spanned by the x and y axes. Lateral dimensions (for example lateral distances, lateral cross-sectional areas, lateral surfaces, lateral extents, lateral shifts etc.) may therefore relate to dimensions in the xy plane and vertical dimensions may relate to dimensions in the z direction, perpendicular to the xy plane. The vertical extent of a layer in the z direction can therefore be referred to as the layer thickness, for example.

The layer stack of the magnetoresistive sensor element 100 comprises at least one reference layer with a reference magnetization (for example a reference direction in the case of GMR or TMR technology). The reference magnetization is a magnetization direction that provides a sensor direction corresponding to a sensor axis of the magnetoresistive sensor element 100. The reference layer and consequently the reference magnetization define a sensor plane. The sensor plane may be defined by the xy plane, for example. The x direction and the y direction can therefore be referred to as “in-plane” with respect to the sensor plane and the z direction can be referred to as “out-of-plane” with respect to the sensor plane.

Accordingly, in the case of a GMR sensor element or a TMR sensor element, the resistance of the magnetoresistive sensor element 100 is at a minimum if the magnetically free magnetization of a magnetically free layer points exactly in the same direction as the reference magnetization (for example the reference direction), and the resistance of the magnetoresistive sensor element 100 is at a maximum if the magnetically free magnetization of the magnetically free layer points exactly in the opposite direction to the reference magnetization. The orientation of the magnetically free magnetization of the magnetically free layer is variable when an external magnetic field is present. Therefore, the resistance of the magnetoresistive sensor element 100 can vary based on an influence of the external magnetic field on the magnetically free magnetization of the magnet-free layer.

From the bottom to the top, the magnetoresistive sensor element 100 may comprise an optional seed layer 102 which can be used to influence and/or optimize stack growth. In some implementations, the seed layer 102 may be composed of copper, tantalum, ruthenium or a combination thereof. In the example shown, a natural antiferromagnetic (NAF) layer 104 is formed on the seed layer 102 or is arranged elsewhere. The NAF layer 104 may be composed of platinum-manganese (PtMn), iridium-manganese (IrMn), nickel-manganese (NiMn) or the like. The layer thickness of the NAF may be in the range of 5 nm to 50 nm, for example.

In addition, a pinned layer (PL) 106 may be formed on the NAF layer 104 or arranged elsewhere. The pinned layer 106 may be composed of a ferromagnetic material, for example cobalt-iron (CoFe) or cobalt-iron-boron (CoFeB). Contact between the NAF layer 104 and the pinned layer 106 may cause an effect that is known as the exchange bias effect and causes the magnetization of the pinned layer 106 to be oriented in a preferred direction (for example in the x direction, as illustrated). The magnetization of the pinned layer 106 may be referred to as pinned magnetization. The pinned layer 106 may have a closed flux magnetization pattern (vortex) in the xy plane. This closed flux magnetization pattern of the pinned layer 106 may be produced when producing the magnetoresistive sensor element 100 and may be permanently fixed. Alternatively, the pinned layer 106 may have a linear magnetization pattern in the xy plane (for example a homogeneous orientation in one direction) that is permanently fixed.

The magnetoresistive sensor element 100 also comprises an non-magnetic layer (NML) which is referred to as a coupling intermediate layer 108. In one possible implementation, the coupling intermediate layer 108 may comprise, for example, ruthenium, iridium, copper, copper alloys or similar materials. Other materials (for example paramagnets) are likewise possible. A magnetic (for example ferromagnetic) reference layer (RL) 110 may be formed on the coupling intermediate layer 108 or arranged elsewhere. The thickness of the pinned layer 106 and of the magnetic reference layer 110 may be in the range of 1 nm to 10 nm.

Accordingly, the coupling intermediate layer 108 may be arranged between the pinned layer 106 and the magnetic reference layer 110 in order to spatially separate the pinned layer 106 and the magnetic reference layer 110 in the vertical direction. In addition, the coupling intermediate layer 108 may provide intermediate layer exchange coupling (for example antiferromagnetic Ruderman-Kittel-Kasuya-Yosida (RKKY) coupling) between the pinned layer 106 and the magnetic reference layer 110 in order to form an artificial antiferromagnet. Consequently, a magnetization of the magnetic reference layer 110 may be oriented and kept in a direction that is antiparallel to or opposite the magnetization of the pinned layer 106 (for example in the x direction, as illustrated). The magnetization of the magnetic reference layer 110 can be referred to as reference magnetization.

Since the NAF layer 104 is configured such that it orients and fixes the magnetization of the pinned layer 106 in a particular direction and the coupling intermediate layer 108 is configured such that it orients and fixes the magnetization of the magnetic reference layer 110 in an opposite direction, it can be the that the NAF layer 104 is configured to keep the magnetization of the pinned layer 106 (for example a fixed magnetization) in a first magnetic orientation and to keep the magnetization of the magnetic reference layer 110 (for example a fixed reference magnetization) in a second magnetic orientation. If, for example, the pinned layer 106 has a flux magnetization pattern (vortex magnetization pattern) closed in the clockwise direction in the xy plane, the magnetic reference layer 110 may have a flux magnetization pattern (vortex magnetization pattern) closed in the anticlockwise direction in the xy plane (or vice versa). In this manner, the magnetic reference layer 110 may have a permanent closed-flux magnetization pattern. Alternatively, the magnetic reference layer 110 may have a linear magnetization pattern in a particular direction in the xy plane if the pinned layer 106 has a linear magnetization pattern in an antiparallel direction. Therefore, the NAF layer 104, the pinned layer 106, the coupling intermediate layer 108 and the magnetic reference layer 110 form a magnetic reference layer system 112 of the magnetoresistive sensor element 100.

The magnetoresistive sensor element 100 additionally comprises a barrier layer 114 (for example a tunnel barrier) which is vertically arranged between the reference layer system 112 and a magnet-free layer 116. The barrier layer 114 may be formed, for example, on the magnetic reference layer 110 of the reference layer system 112 or arranged elsewhere, and the magnetically free layer 116 may be formed on the barrier layer 114 or arranged elsewhere.

The barrier layer 114 may be composed of a non-magnetic material. In some implementations, the barrier layer 114 may be an electrically insulating tunnel barrier layer. For example, the barrier layer 114 may be a tunnel barrier layer which is used to produce a TMR effect. The barrier layer 114 may be composed of magnesium oxide (MgO) or another material with similar properties.

The material of the magnetically free layer 116 be an alloy of a ferromagnetic material, for example CoFe, CoFeB or NiFe. The magnetostriction constant of the magnetically free layer 116 can be adjusted using the iron content. The magnetically free layer 116 has a magnetically free magnetization that is variable when an external magnetic field is present. Therefore, the magnetically free layer 116 may be referred to as a sensor layer since changes in the magnetically free magnetization are used to determine a measurement variable. In addition, the magnetically free magnetization has a magnetic standard orientation (for example a linear or vortex magnetization) in a basic state. The basic state is a state in which the influence of the external magnetic field on the magnetically free layer 116 is not present or is negligibly small. In some implementations, the magnetoresistive sensor element 100 may comprise a magnetically free system containing a multiplicity of layers (for example two or more magnetically free layers) which act in combination as a magnetically free layer. In this case, the magnetically free layers of the magnetically free system are magnetically coupled to one another. The magnetically free system can therefore act as a magnetically free layer, but may also consist of a plurality of layers. The magnetically free system has a magnetically free magnetization, wherein the magnetically free magnetization is variable when the external magnetic field is present.

A covering layer 118, for example made of tantalum (Ta), tantalum nitride (TaN), ruthenium (Ru), titanium (Ti), titanium nitride (TiN), platinum (Pt) or the like, may be formed on the magnetically free layer 116 or arranged elsewhere in order to form an upper layer of the magnetoresistive sensor element 100.

The seed layer 102 may be used as a lower electrode or may establish electrical contact with a lower electrode (not illustrated) of the magnetoresistive sensor element 100. The covering layer 118 may establish electrical contact with an upper electrode (not illustrated) of the magnetoresistive sensor element 100. The barrier layer 114 may be configured such that electrons can tunnel between the reference layer system 112 and the magnetically free layer 116 if a bias voltage is applied to the electrodes of the magnetoresistive sensor element 100 (not illustrated) in order to produce a magnetoresistance effect (for example a TMR effect).

As mentioned above, FIG. 1 is used only as an example of an xMR sensor element. Other examples may differ from the description in FIG. 1. The number and arrangement of the components shown in FIG. 1 is an example. In practice, the xMR sensor element 100 may contain additional elements or layers, fewer elements, different elements or differently arranged elements than those shown in FIG. 1.

FIG. 2 shows a diagram 200 of an inverse magnetostrictive effect according to one or more implementations. The diagram 200 shows the inverse magnetostrictive effect for the magnetically free layer 116. A force that causes a mechanical stress in the magnetically free layer 116 along a mechanical stress axis 202 may be exerted on the magnetically free layer 116. The force may be a compressive or tensile force which deforms the magnetically free layer 116 in a dimension running parallel or perpendicular to the mechanical stress axis 202. In the case of a positive magnetostriction constant, the magnetization of the magnetically free layer 116 tends to align with a tensile stress. In this example, the induced mechanical stress results in a magnetization axis 204 of the magnetically free layer 116 being shifted in order to be oriented parallel to the axis 202 of the mechanical stress. Consequently, the magnetization of the magnetically free layer 116 that is aligned with the magnetization axis 204 is oriented parallel to the axis 202 of the mechanical stress. By controlling the manner in which the force is exerted on the magnetically free layer 116 and controlling the direction of the induced mechanical stress, the orientation of the magnetization axis 204 can be controlled such that it is oriented in a desired direction without orientation errors.

In some implementations, the magnetization axis 204 can be oriented in a different direction to the mechanical stress axis 202. For example, the magnetization axis 204 may be oriented perpendicular to the mechanical stress axis 202. The orientation of the magnetization axis 204 relative to the mechanical stress axis 202 may depend on the material of the magnetically free layer 116 (for example the magnetostriction constant). The mechanical stress axis 202 may be controlled based on the magnetostriction constant of the magnetically free layer 116 in order to control the orientation of the magnetization axis 204. The magnetostriction constant of the magnetically free layer 116 may be influenced by a choice of material of the magnetically free layer 116. According to some implementations, the magnetically free layer has an iron alloy, for example CoFe, CoFeB, NiFe, etc. The magnetostriction constant of the magnetically free layer 116 can be adjusted using the iron content.

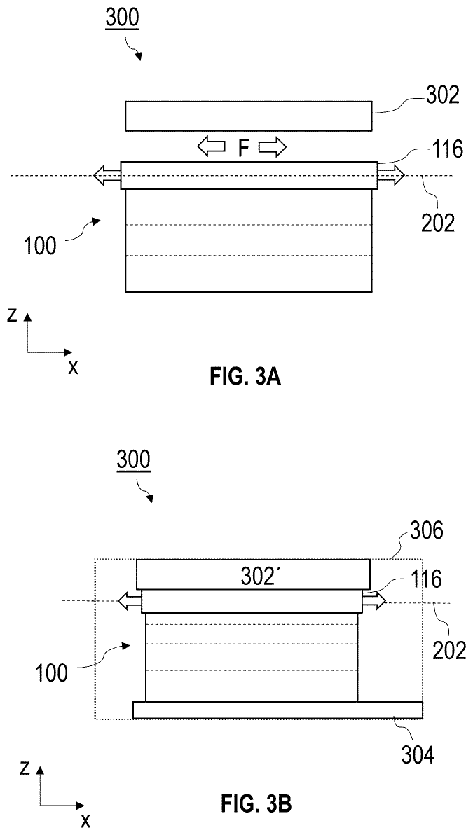

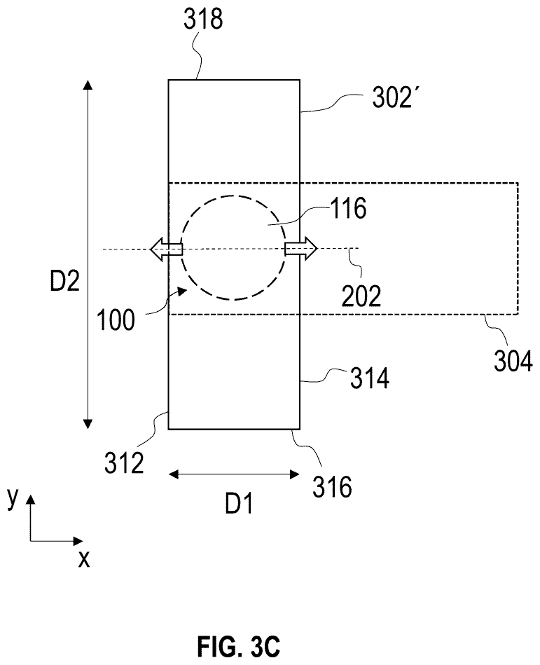

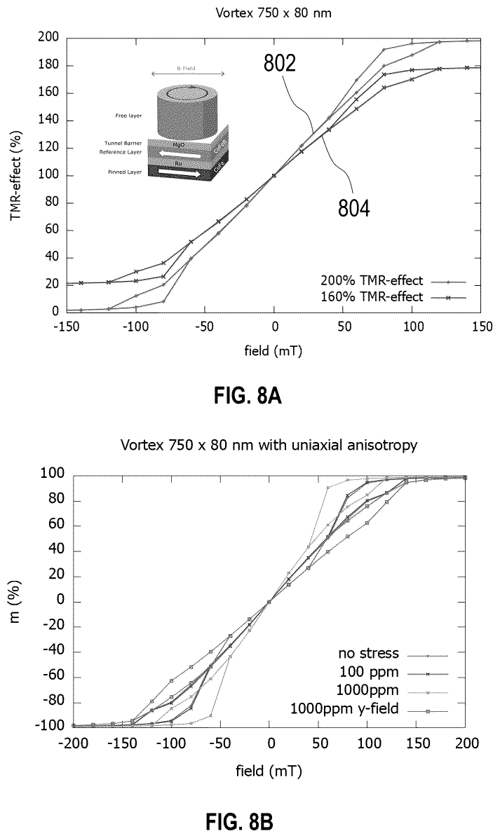

FIG. 3A shows an implementation of a magnetoresistive sensor 300 having a magnetoresistive sensor element 100. The magnetoresistive sensor element 100 has a layer stack which, in addition to the other layers described above by way of example, comprises the magnetically free layer 116. The magnetically free layer 116 may have a rectilinear magnetization or a vortex magnetization. A measurement sensitivity (sensitivity) of the xMR sensor element 100 is temperature-dependent. This is shown in FIG. 8A. The curve 802 shows a TMR effect (higher measurement sensitivity) of a TMR sensor element 100 at a low temperature, and the curve 804 shows a TMR effect (lower measurement sensitivity) at a higher temperature.

The magnetoresistive sensor 300 comprises a device 302 which is configured to cause or induce a temperature-dependent mechanical stress in the magnetically free layer 116 of the magnetoresistive sensor element 100. The temperature-dependent mechanical stress causes temperature-dependent mechanical deformation of the magnetically free layer 116 (inverse magnetostriction), as a result of which the measurement sensitivity of the magnetoresistive sensor element 100 can be made (more) independent of the temperature. For this purpose, the device 302 may be configured to exert a temperature-dependent mechanical force F on the magnetically free layer 116 in order to induce the mechanical stress in the magnetically free layer 116 along the mechanical stress axis 202. Although FIG. 3A shows, by way of example, the mechanical force F on the magnetically free layer 116 in a manner parallel to the mechanical stress axis 202, implementations are also conceivable in which the mechanical force F is exerted on the magnetically free layer 116 in a manner perpendicular to the mechanical stress axis 202.

According to some implementations, the device 302 may have, for example, one or more piezoelectric actuators which are controlled in a temperature-dependent manner in order to exert the mechanical force F on the magnetically free layer 116 in a manner perpendicular and/or parallel to the mechanical stress axis 202. Alternatively or additionally, the device may have one or more stress-inducing layers which are mechanically permanently coupled to the layer stack or the magnetically free layer 116 and are configured to exert the temperature-dependent force F on the magnetically free layer 116 in order to induce the mechanical stress in the magnetically free layer 116 along the mechanical stress axis 202. On account of its coefficient of thermal expansion, the stress-inducing layer expands (or contracts) in a temperature-dependent manner and thereby transmits the force F to the magnetically free layer 116. For this purpose, the stress-inducing layer may be mechanically coupled directly or indirectly to the magnetically free layer 116. In the case of direct coupling, the stress-inducing layer vertically or laterally directly adjoins the magnetically free layer 116. In the case of indirect coupling, further material is arranged between the stress-inducing layer and the magnetically free layer 116. A material of the stress-inducing layer preferably has a coefficient of thermal expansion of greater than 10 ppm/K, greater than 15 ppm/K, or even greater than 20 ppm/K. Examples of such materials of the stress-inducing layer are aluminum, copper or nickel.

FIG. 3B shows an implementation of a magnetoresistive sensor 300, in which the stress-inducing device 302 is in the form of a stress-inducing layer 302′ arranged directly (immediately) above the magnetically free layer 116. The stress-inducing layer 302′ may be electrically conductive and may act as an upper electrode. A lower electrode 304 is arranged below the magnetoresistive sensor element 100, with the result that the magnetoresistive sensor element 100 having the magnetically free layer 116 is embedded between the electrodes 302′ and 304 according to a so-called CPP (current perpendicular to plane) configuration. The lower electrode 304 may likewise have a coefficient of thermal expansion of greater than 10 ppm/K, greater than 15 ppm/K, or even greater than 20 ppm/K. The electrodes 302′, 304 and the magnetoresistive sensor element 100 may be arranged in a common housing or an environment 306. The sensor may be embedded within a semiconductor metallization, and a direct environment may have dielectric materials, for example SiO₂. The stress-inducing layer 302′ may be formed from aluminum (Al) and may therefore have a greater coefficient of thermal expansion than the magnetically free layer 116 of the magnetoresistive sensor element 100. As the temperature increases, the stress-inducing layer 302′ expands to a greater extent than the environment. The resulting temperature-dependent mechanical force F acts on the magnetically free layer 116 and causes an anisotropic length change in the magnetically free layer 116. Forces are produced by the greater expansion of the aluminum in comparison with the surrounding SiO₂, but also in comparison with the adjacent sensor. The aluminum may relax on the outer surfaces of the aluminum by virtue of it pressing into the adjacent layers. These are either compressed or deformed or pass on the forces.

FIG. 3C shows a plan view of the magnetoresistive sensor 300 according to one or more implementations.

The magnetoresistive sensor element 100 comprises a sensor plane (for example an xy plane) which is defined by a first axis (for example an x axis) and a second axis (for example a y axis). The layers of the layer stack are stacked along a third axis (for example a z axis) perpendicular to the sensor plane. In this example, the mechanical stress axis 202 is collinear with the first axis. In other words, the mechanical stress axis 202 is oriented along the first axis (for example the x axis). The stress-inducing layer 302′ also has shape-anisotropic dimensions in the xy plane. For example, the stress-inducing layer 302′ has a first dimension D1, which defines a width of the stress-inducing layer 302′ along the first axis, and a second dimension D2, which defines a length of the stress-inducing layer 302′ along the second axis. The first dimension D1 is therefore smaller than the second dimension D2. Temperature-related deformation of the stress-inducing layer 302′ may therefore be configured such that it is effected at the position of the magnetically free layer 116 mainly along the smaller dimension (for example the first dimension D1) of the stress-inducing layer 302′. Consequently, the mechanical stress axis 202 may be oriented along the first axis (for example the x axis).

Accordingly, the first dimension D1 (for example a width dimension) is defined by a distance between a first side edge 312 and a second side edge 314 of the stress-inducing layer 302′, and the second dimension D2 (for example a length dimension) is defined by a distance between a third side edge 316 and a fourth side edge 318 of the stress-inducing layer 302′. The magnetoresistive sensor element 100 having the magnetically free layer 116 is arranged between the first side edge 312 and the second side edge 314, and the magnetoresistive sensor element 100 having the magnetically free layer 116 is arranged between the third side edge 316 and the fourth side edge 318 of the stress-inducing layer 302′.

The force exerted by the stress-inducing layer 302′ on the magnetoresistive sensor element 100 or its magnetically free layer 116 decreases (for example exponentially) from an edge. For example, a force which causes the mechanical stresses along the x axis decreases with the distance from the first side edge 312 and the second side edge 314. Therefore, the first dimension D1 should be sufficiently small to increase or maximize the induced mechanical stress along the x axis. For example, the first dimension D1 should be so small that the magnetoresistive sensor element 100 having the magnetically free layer 116 can be placed both in the vicinity of the first side edge 312 and in the vicinity of the second side edge 314 in order to increase the stress induced along the x axis. In addition, a force which causes a mechanical stress along the y axis decreases with the distance from the third side edge 316 and the fourth side edge 318. Therefore, the second dimension D2 should be sufficiently large to reduce or minimize the induced mechanical stress along the y axis. For example, the second dimension D2 should be so large that the magnetoresistive sensor element 100 having the magnetically free layer 116 can be placed far enough away from the third side edge 316 and the fourth side edge 318 to minimize the stress induced along the y axis.

In some implementations, the stress-inducing layer 302′ is configured such that it induces an elongation or compression of the layer stack or of the magnetically free layer 116 along the first axis. For example, the stress-inducing layer 302′ may be under compressive stress, with the result that at least the magnetically free layer 116 can expand or lengthen both in the positive x direction and in the negative x direction. In other words, the width or diameter of the magnetically free layer 116 may increase on account of an expansion force exerted on the magnetically free layer 116. In addition, in some implementations, the magnetoresistive sensor element 100 is arranged far enough away from the third side edge 316 and the fourth side edge 318 of the stress-inducing layer 302′ that the stress-inducing layer 302′ causes substantially no elongation or compression of the layer stack in a dimension corresponding to the second axis (for example the y axis). Since the magnetization of the magnetically free layer 116 is preferably oriented along a tensile stress axis, a position of the magnetoresistive sensor element 100 relative to the first side edge 312, the second side edge 314, the third side edge 316 and the fourth side edge 318, in combination with the dimensions of the first dimension D1 and of the second dimension D2, can ensure that the mechanical stress axis (for example the tensile stress axis) 202 is oriented in a desired direction in order to align the magnetization axis with this desired direction. A mechanical stress of the magnetically free layer 116 along the x direction produces uniaxial anisotropy the and increases the measurement sensitivity of the sensor element 100 in the x direction at the expense of the measurement sensitivity in the y direction (if the reference system is oriented along the y axis). For example, in some implementations, the measurement sensitivity can be increased by 5% in the x direction if the magnetically free layer 116 is elongated by 200 ppm in the x direction. Aluminum has a coefficient of thermal expansion of 23 ppm/K, which can result in elongation of greater than 1000 ppm per 50° C. temperature increase.

As already mentioned, FIGS. 3A to 3C serve only as examples. Other examples may differ from that which was described with respect to FIGS. 3A to 3C.

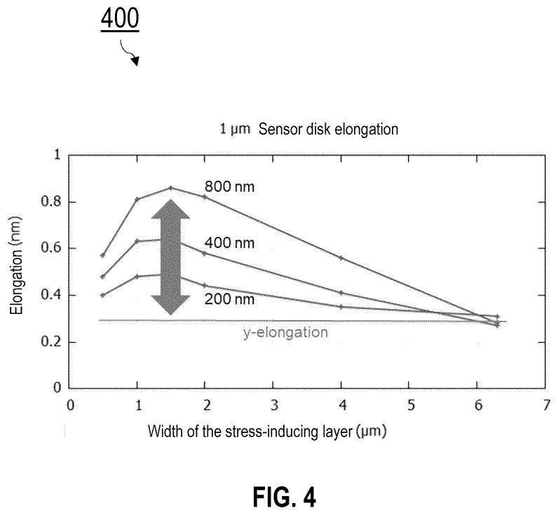

FIG. 4 is a diagram 400 showing the elongation of a sensor element 100 or its magnetically free layer 116 based on the width D1 and the thickness of the stress-inducing layer 302′ according to one or more implementations. In this simulation, the thermal expansion is produced by a temperature increase of 100° C. The diagram 400 can correspond to the magnetoresistive sensor 300 which was described in connection with FIGS. 3B and 3C. The diagram 400 shows the elongation of the sensor element 100 or its magnetically free layer 116 both in the x direction and in the y direction, wherein the width (for example the first dimension D1) of the stress-inducing layer 302′ is varied along the x axis and the length (for example the second dimension D2) of the stress-inducing layer 302′ is fixed along the y axis (for example at 5.25 μm). The x direction may be the desired direction for the uniaxial anisotropy.

The elongation of the magnetically free layer 116 may be measured in nanometers (nm) and the width of the stress-inducing layer 302′ may be measured in micrometers (μm) in the x direction. The diagram 400 relates to a sensor element 100 having a diameter of the magnetically free layer 116 of 1 μm. The layer stack of a sensor element 100 may generally be disk-shaped or cylindrical. Higher mechanical stresses induced in a temperature-dependent manner result in a stronger temperature-dependent elongation of the sensor element or its magnetically free layer 116, which in turn has a greater influence on the anisotropy in a desired direction. Therefore, it is possible to maximize the induced mechanical stress or elongation in the x direction. The temperature increase also results in an approximately constant elongation in the y direction. In other words, the aspect ratio between the elongation in the x direction and the elongation in the y direction can be maximized in order to achieve maximum anisotropy of the magnetization in the magnetically free layer 116. The anisotropy increases up to 1.5 μm with the width D1, since the forces at the edge of the stress-inducing layer 302′ increase with the width D1. If the width D1 increases further, however, the anisotropy falls again, since the distance between the edge of the stress-inducing layer 302′ and the sensor element 100 increases. The anisotropy can be increased further by increasing the thickness of the stress-inducing layer 302′ from 200 nm to 800 nm, for example.

According to the diagram 400, the maximum anisotropy is achieved with a width of approximately 1.5 μm of the stress-inducing (metal) layer 302′, wherein the ratio of the elongation in the x direction to the elongation in the y direction is maximized. The anisotropy that can be achieved can increase with increasing thickness (in the z direction) of the stress-inducing layer 302′.

Accordingly, the stress-inducing layer 302′ may be configured such that it causes an elongation of the magnetically free layer 116 by a first percentage in one dimension (for example an x direction) along the x axis and an elongation of the magnetically free layer 116 by a second percentage along the y axis. The first percentage is at least twice as high as the second percentage in order to increase the anisotropy of the magnetically free layer 116. In some implementations, the first percentage is at least three times as high as the second percentage.

In some implementations, the sensor element 100 or its magnetically free layer 116 has a diameter in the range of 0.5-1.5 μm, and the mechanical stress axis is collinear with the x axis. The stress-inducing layer 302′ may have a first dimension D1 along the x axis and a second dimension D2 along the y axis. The second dimension D2 may be at least twice as large as the first dimension D1, wherein the first dimension is in a range of 1.0-3.0 μm in order to produce an aspect ratio that is sufficiently large to cause uniaxial anisotropy in the x direction and to increase the measurement sensitivity of the sensor element 100 in the x direction in a temperature-dependent manner.

In some implementations, the stress-inducing layer 302′ may have a width dimension in a range of 1-3 μm, which is defined by the first side edge 312 and the second side edge 314, and a length dimension which is defined by the third side edge 316 and the fourth side edge 318. The layer stack is arranged between the first side edge 312 and the second side edge 314 in the x direction and between the third side edge 316 and the fourth side edge 318 in the y direction. The layer stack has an outer circumference that may have first distances which are no more than 2 μm from the first side edge 312 or the second side edge 314. In other words: The layer stack or the magnetically free layer 116 of the magnetoresistive sensor element 100 is no further than 2 μm away from the first side edge 312 or the second side edge 314, for example. Therefore, a closest point of the layer stack or of the magnetically free layer 116 to the first side edge 312 is no more than 2 μm away and a closest point of the layer stack or of the magnetically free layer 116 to the second side edge 314 is no more than 2 μm away. The sensor element 100 or the magnetically free layer 116 may have a diameter in the range of 0.3-1.5 μm, with the result that this condition is met for a stress-inducing layer 302′ having a width in the range of 1-3 μm.

In addition, the outer circumference of the layer stack or of the magnetically free layer 116 may have second distances which are more than 2 μm from the third side edge 316 or the fourth side edge 318. In other words, the layer stack or the magnetically free layer 116 of the magnetoresistive sensor element 300 is at least 2 μm away from the third side edge 316 and at least 2 μm away from the fourth side edge 318, for example. Therefore, a closest point of the layer stack or of the magnetically free layer 116 to the third side edge 316 is more than 2 μm and a closest point of the layer stack or of the magnetically free layer 116 to the fourth side edge 318 is more than 2 μm.

In addition, a minimum distance of the second distances may be at least twice as large as a maximum distance of the first distances.

As a result of this configuration, it is possible to produce an aspect ratio of the stress-inducing layer 302′ that is sufficiently large to orient the magnetization 204 along the x axis.

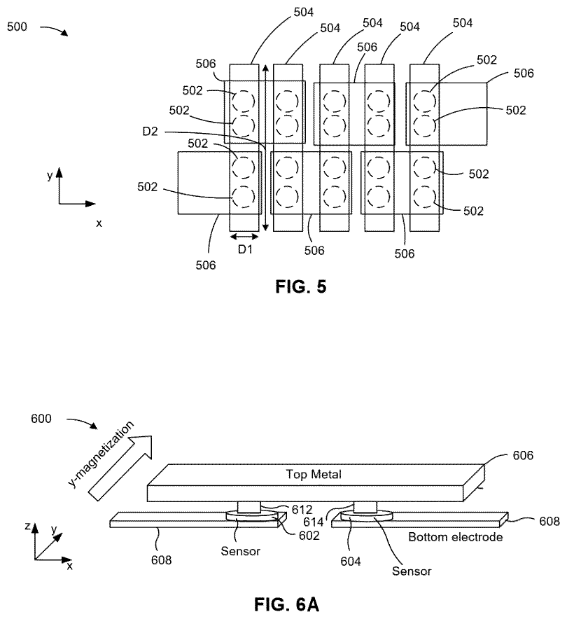

FIG. 5 shows a plan view of a magnetoresistive sensor 500 according to one or more implementations. The magnetoresistive sensor 500 comprises a plurality of sensor elements 502 which are arranged between a respective upper conductor 504 (for example an upper metal layer) and a respective lower conductor 506 (for example a lower electrode). Stress-inducing layers may each be formed by the upper conductors 504 and/or the lower conductors 506. In this case, the upper conductors 504 and/or lower conductors 506 may be produced from aluminum. The upper conductors 504 and/or the lower conductors 506 may have lateral dimensions which comply with the aspect ratio described above. Consequently, a temperature-dependent mechanical stress may be induced in each magnetically free layer 116 of the sensor elements 502 along a mechanical stress axis which is oriented along the x axis. As a result, the measurement sensitivity of the magnetoresistive sensor system 500 can be increased in a temperature-dependent manner in order to compensate for a TMR effect that is reduced in a temperature-dependent manner.

Accordingly, each upper electrode 504 may be a straight (rod-shaped) structure with a first dimension D1 in the x direction and a second dimension D2 in the y direction. The first dimension D1 may be smaller than the second dimension D2. The upper electrode 504 is subject to a temperature-dependent stress which results in a force that is exerted on each magnetically free layer 116 of the sensor elements 502. The sensor elements 502 which are connected to the same upper electrode 504 are spaced apart from one another in the y direction. In addition, the x direction runs parallel to the mechanical stress axes of the sensor elements 502.

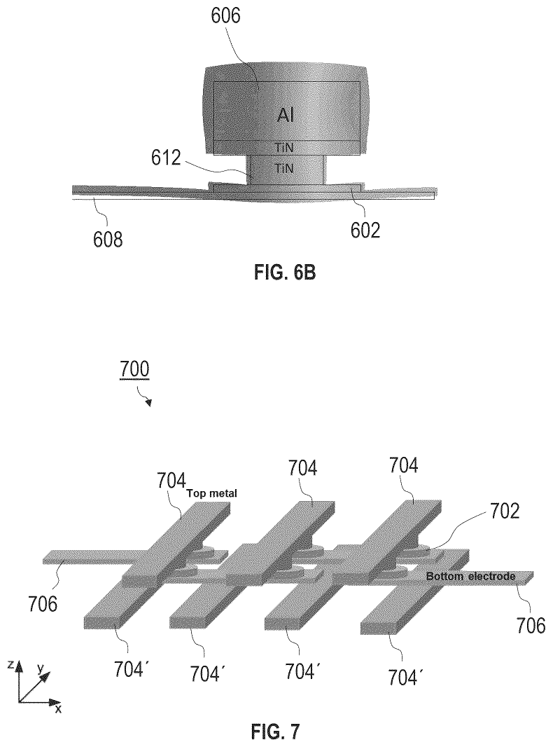

FIG. 6A shows a magnetoresistive sensor 600 according to one or more implementations. The magnetoresistive sensor 600 comprises a first sensor element 602 and a second sensor element 604, which are arranged between an upper conductor 606 (for example an upper metal layer) and a corresponding lower conductor 608 (for example a lower electrode). The upper conductor 606 and/or the lower conductor 608 may be formed from aluminum and may act as a stress-inducing layer 610. A first via 612 can couple the first sensor element 602 to the upper conductor 606, and a second via 614 can couple the second sensor element 604 to the upper conductor 606. The vias 612, 614 between the stress-inducing layer 606 and the sensor elements 602, 604 may comprise an electrically conductive material for transmitting forces which is harder than the stress-inducing layer 606. For example, the vias 612, 614 may be formed from an electrically conductive ceramic, for example TiN.

The aspect ratio of the upper conductor 606 is configured such that the upper conductor 606 is deformed mainly in the y direction at the positions of the sensor elements 602 and 604 in the event of a temperature change and induces a first mechanical stress in the first sensor element 602 in the y direction and a second mechanical stress in the second sensor element 604 in the y direction. For example, the upper conductor 606 may have lateral dimensions which comply with the configuration of the aspect ratio, as described in a similar manner above in connection with FIGS. 3B, 3C, with the exception that the width dimension of the stress-inducing layer 610 extends in the y direction and the length dimension of the stress-inducing layer 610 extends in the x direction.

FIG. 6B shows an example arrangement comprising a lower conductor 608, on which the magnetoresistive sensor element 602 is arranged. The force-transmitting via 612 with a smaller diameter than the sensor element 602 is arranged on the sensor element 602. An optional, further TiN layer with a larger diameter than the via 612 is situated above the sensor element. The Al layer 606, as the stress-inducing layer, is situated above the TiN layer. In the event of a temperature increase (for example from the left), the Al layer 606 expands, as a result of which the via 612 is pressed onto the magnetically free layer of the sensor element 602 and thus causes the mechanical stress. The force on the sensor element 602 may increase with increasing thickness of the Al layer 606. Depending on the thickness of the Al layer 606, its thermal expansion is elastic up to a particular temperature. For example, the thermal expansion is elastic below 100° C. for thick aluminum (2 μm). Thinner aluminum of less than 1 μm is elastic up to 200° C., for example.

FIG. 7 shows a magnetoresistive sensor 700 according to one or more implementations. The magnetoresistive sensor 700 comprises a plurality of sensor elements 702 which are arranged between a respective upper conductor 704 (for example an upper metal layer) and a respective lower conductor 706 (for example a lower electrode). In this case, two sensor elements 702 which are adjacent in the x direction are assigned to a common lower conductor 706 running in the x direction, but are assigned to adjacent upper conductors 704 running in the y direction. Two sensor elements 702 which are adjacent in the y direction are assigned to a common upper conductor 704 running in the y direction, but are assigned to adjacent lower conductors 706 running in the x direction. The upper conductors 704 form stress-inducing layers which may have lateral dimensions which comply with the configuration of the aspect ratio described above in connection with FIGS. 3B, 3C. Further stress-inducing layers 704′, for example made of aluminum, are arranged below the lower rod-shaped conductors 706 running in the x direction. The further stress-inducing layers 704′ may have lateral dimensions which comply with the configuration of the aspect ratio described above in connection with FIGS. 3B, 3C. In the implementation shown, the lower stress-inducing Al tracks 704′ are arranged in the x direction with an offset with respect to the upper stress-inducing Al tracks 704. In other words, a lower stress-inducing Al track 704′ is arranged in the x direction between two upper stress-inducing Al tracks 704. The further stress-inducing layers 704′ are mechanically coupled to the lower electrodes 706 and are configured to exert a further temperature-dependent mechanical force on the lower electrodes 706 in order to induce the mechanical stress in the magnetically free layer of the sensor elements 702.

The lateral dimensions of the upper and lower stress-inducing layers 704, 704′ are configured such that a corresponding mechanical stress is induced on each of the sensor elements 702 in the x direction. Consequently, the mechanical stress can be induced in each layer stack of the multiplicity of sensor elements 702 along a mechanical stress axis that is oriented along the x axis in order to increase the measurement sensitivity, for example along the x axis.

Example implementations of the present disclosure propose a concept for adjusting the temperature coefficient of the measurement sensitivity of xMR sensors using thermal expansion and magnetostriction. As a result of the temperature-dependent mechanical stress in the magnetically free layer and the associated magnetostriction, the measurement sensitivity of xMR sensors can be influenced such that the temperature dependence of the measurement sensitivity can be approximately compensated for. This is illustrated in FIG. 8B for different mechanical stresses in the magnetically free layer.

The aspects and features described in connection with a particular one of the previous examples may also be combined with one or more of the other examples to replace an identical or similar feature of this other example or to introduce the feature additionally into the other example.

Furthermore, it goes without saying that the disclosure of multiple steps, processes, operations or functions disclosed in the description or claims should not be interpreted as necessarily being in the described order, unless this is explicitly stated in the individual case or is mandatory for technical reasons. Therefore, the previous description does not restrict the execution of multiple steps or functions to a specific order. Furthermore, in other examples, a single step, a single function, a single process or a single operation may include and/or be broken into multiple substeps, subfunctions, subprocesses or suboperations.

If some aspects have been described in the preceding sections in connection with an apparatus or system, these aspects should also be understood as a description of the corresponding method. In this case, for example, a block, an apparatus or a functional aspect of the apparatus or the system may correspond to a feature, such as a method step, of the corresponding method. Correspondingly, aspects described in connection with a method should also be understood as a description of a corresponding block, a corresponding element, a property or a functional feature of a corresponding apparatus or of a corresponding system.

The following claims are hereby incorporated into the detailed description, each claim being independent as a separate example. It should also be noted that—although a dependent claim in the claims refers to a particular combination with one or more other claims—other examples may also comprise a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

In some implementations, a magnetoresistive sensor includes a sensor element having a layer stack which comprises a magnetically free layer with a magnetically free magnetization, wherein a measurement sensitivity of the sensor element is temperature-dependent; and a device configured to induce a temperature-dependent mechanical stress in the magnetically free layer.

In some implementations, the device is configured to exert a temperature-dependent mechanical force on the magnetically free layer in order to induce the temperature-dependent mechanical stress in the magnetically free layer along a mechanical stress axis.

In some implementations, the device is configured to exert the temperature-dependent mechanical force on the magnetically free layer in a manner perpendicular or parallel to the mechanical stress axis in order to deform the magnetically free layer.

In some implementations, the device has a stress-inducing layer which is mechanically coupled to the layer stack and is configured to exert a temperature-dependent force on the magnetically free layer in order to induce the temperature-dependent mechanical stress in the magnetically free layer.

In some implementations, the stress-inducing layer has shape anisotropy.

In some implementations, a material of the stress-inducing layer has a coefficient of thermal expansion of greater than 10 ppm/K.

In some implementations, the stress-inducing layer has a metal layer comprising aluminum, copper or nickel.

In some implementations, the layer stack is arranged between a first electrode and a second electrode of the sensor element, and the stress-inducing layer is formed by the first electrode.

In some implementations, a further device which is mechanically coupled to the second electrode and is configured to exert a further temperature-dependent mechanical force on the second electrode in order to induce the temperature-dependent mechanical stress in the magnetically free layer.

In some implementations, an electrically conductive material, for transmitting force, is arranged between the stress-inducing layer and the layer stack, wherein the electrically conductive material is harder than the stress-inducing layer.

In some implementations, the magnetically free layer has an iron alloy.

In some implementations, the sensor element comprises a TMR sensor element.

In some implementations, the magnetically free layer has a vortex magnetization.

In some implementations, a method for influencing a temperature-dependent measurement sensitivity of a magnetoresistive sensor includes arranging at least one sensor element having a layer stack on a substrate, wherein the layer stack comprises a magnetically free layer with a magnetically free magnetization; and exerting a temperature-dependent mechanical force on the magnetically free layer of each sensor element of the at least one sensor element in order to induce a mechanical stress in the magnetically free layer of each sensor element.

In some implementations, a magnetoresistive sensor comprising: a TMR sensor element having a magnetically free layer, wherein a measurement sensitivity of the TMR sensor element is temperature-dependent; and a stress-inducing layer which is mechanically coupled to the TMR sensor element, has a coefficient of thermal expansion, and is configured to induce a temperature-dependent mechanical stress in the magnetically free layer.

In some implementations, the TMR sensor element is arranged between a first electrode and a second electrode, and the stress-inducing layer is formed by the first electrode.

In some implementations, wherein the stress-inducing layer has shape anisotropy.

In some implementations, the stress-inducing layer is configured to induce the temperature-dependent mechanical stress in the magnetically free layer such that the temperature-dependent mechanical stress compensates for the measurement sensitivity of the TMR sensor element as temperature changes.

In some implementations, the stress-inducing layer is configured to induce the temperature-dependent mechanical stress in the magnetically free layer to change a magnetic property of the magnetically free layer in a temperature-dependent manner such that the measurement sensitivity of the TMR sensor element remains substantially constant.

1. A magnetoresistive sensor, comprising:
a sensor element having a layer stack which comprises a magnetically free layer with a magnetically free magnetization,
wherein a measurement sensitivity of the sensor element is temperature-dependent; and
a device configured to induce a temperature-dependent mechanical stress in the magnetically free layer.

2. The magnetoresistive sensor as claimed in claim 1, wherein the device is configured to exert a temperature-dependent mechanical force on the magnetically free layer in order to induce the temperature-dependent mechanical stress in the magnetically free layer along a mechanical stress axis.

3. The magnetoresistive sensor as claimed in claim 2, wherein the device is configured to exert the temperature-dependent mechanical force on the magnetically free layer in a manner perpendicular or parallel to the mechanical stress axis in order to deform the magnetically free layer.

4. The magnetoresistive sensor as claimed in claim 1, wherein the device has a stress-inducing layer which is mechanically coupled to the layer stack and is configured to exert a temperature-dependent force on the magnetically free layer in order to induce the temperature-dependent mechanical stress in the magnetically free layer.

5. The magnetoresistive sensor as claimed in claim 4, wherein the stress-inducing layer has shape anisotropy.

6. The magnetoresistive sensor as claimed in claim 4, wherein a material of the stress-inducing layer has a coefficient of thermal expansion of greater than 10 ppm/K.

7. The magnetoresistive sensor as claimed in claim 4, wherein the stress-inducing layer has a metal layer comprising aluminum, copper or nickel.

8. The magnetoresistive sensor as claimed in claim 4, wherein the layer stack is arranged between a first electrode and a second electrode of the sensor element, and the stress-inducing layer is formed by the first electrode.

9. The magnetoresistive sensor as claimed in claim 8, also comprising:
a further device which is mechanically coupled to the second electrode and is configured to exert a further temperature-dependent mechanical force on the second electrode in order to induce the temperature-dependent mechanical stress in the magnetically free layer.

10. The magnetoresistive sensor as claimed in claim 4, further comprising:
an electrically conductive material for transmitting force arranged between the stress-inducing layer and the layer stack,
wherein the electrically conductive material is harder than the stress-inducing layer.

11. The magnetoresistive sensor as claimed in claim 1, wherein the magnetically free layer has an iron alloy.

12. The magnetoresistive sensor as claimed in claim 1, wherein the sensor element comprises a tunnel magnetoresistance (TMR) sensor element.

13. The magnetoresistive sensor as claimed in claim 13, wherein the magnetically free layer has a vortex magnetization.

14. A method for influencing a temperature-dependent measurement sensitivity of a magnetoresistive sensor, comprising:
arranging at least one sensor element having a layer stack on a substrate, wherein the layer stack comprises a magnetically free layer with a magnetically free magnetization; and
exerting a temperature-dependent mechanical force on the magnetically free layer of each sensor element of the at least one sensor element in order to induce a mechanical stress in the magnetically free layer of each sensor element.

15. A magnetoresistive sensor comprising:
a tunnel magnetoresistance (TMR) sensor element having a magnetically free layer, wherein a measurement sensitivity of the TMR sensor element is temperature-dependent; and
a stress-inducing layer which is mechanically coupled to the TMR sensor element, has a coefficient of thermal expansion, and is configured to induce a temperature-dependent mechanical stress in the magnetically free layer.

16. The magnetoresistive sensor as claimed in claim 13, wherein the TMR sensor element is arranged between a first electrode and a second electrode, and the stress-inducing layer is formed by the first electrode.

17. The magnetoresistive sensor as claimed in claim 15, wherein the stress-inducing layer has shape anisotropy.

18. The magnetoresistive sensor as claimed in claim 15, wherein the stress-inducing layer is configured to induce the temperature-dependent mechanical stress in the magnetically free layer such that the temperature-dependent mechanical stress compensates for the measurement sensitivity of the TMR sensor element as temperature changes.

19. The magnetoresistive sensor as claimed in claim 15, wherein the stress-inducing layer is configured to induce the temperature-dependent mechanical stress in the magnetically free layer to change a magnetic property of the magnetically free layer in a temperature-dependent manner such that the measurement sensitivity of the TMR sensor element remains substantially constant.
